(19) United States
(12) Patent Application Publication
(10) Pub. No.: US 2022/0113773 A1
(43) Pub. Date: Apr. 14, 2022

(54) ADD-IN CARD HAVING HIGH PERFORMANCE SEMICONDUCTOR CHIP PACKAGES WITH DEDICATED HEAT

(71) Applicant: Intel Corporation, Santa Clara, CA (US)

(72) Inventors: Lunyu MA, Portland, OR (US); Shahin AMIRI, Richmond Hill (CA); Casey CARTE, Hillsboro, OR (US); Mirui WANG, Oshawa (CA); Damion SEARLS, Portland, OR (US); Tamara J. LOW FOON, Toronto (CA)

(73) Assignee: Intel Corporation, Santa Clara, CA (US)

(21) Appl. No.: 17/560,630

(22) Filed: Dec. 23, 2021

(51) Int. Cl. G06F 1/18; G06F 13/42

(52) U.S. Cl. CPC G06F 1/189; G06F 2213/0026; G06F 13/4221; G06F 1/188

(57) ABSTRACT

An apparatus is described. The apparatus includes an add-in card having multiple semiconductor chip packages mounted to a printed circuit board of the add-in card. The add-in card includes separate dedicated heat sinks respectively coupled to the semiconductor chip packages with spring loaded fixturing elements, a heat pipe coupled to a plurality of the heat sinks.

### BACKGROUND

System design engineers face challenges, especially with respect to high performance data center computing, as both computers and networks continue to pack increased levels of performance resulting in higher heat dissipation. Creative packaging solutions are therefore being designed to keep pace with the thermal requirements of such aggressively designed systems.

### FIGURES

FIG. 1 shows a side view of a prior art add-in card;

FIGS. 2a and 2b show another prior art add-in card;

FIG. 3a shows features of an improved add-in card;

FIG. 3b shows different form factor cards that can adopt features of the improved add-in card of FIG. 3a.

FIG. 4 shows a system;

FIG. 5 shows a data center;

FIG. 6 shows a rack.

### DETAILED DESCRIPTION

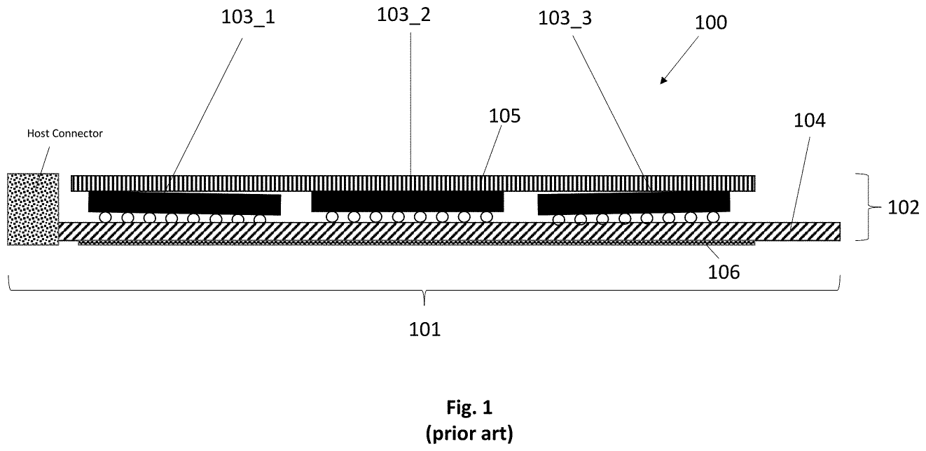

FIG. 1 shows a side view of a first prior art accelerator add-in card 100. An add-in card is a small form factor printed circuit board (PCB) (also referred to as an electronic circuit board) with integrated electronic circuitry (packaged semiconductor chips) that plugs into a larger circuit board such as the motherboard of a computer system (the motherboard has a socket that a connector of the add-in card plugs into).

The accelerator add-in card of FIG. 1 is a “long” Peripheral Component Interface Express (PCIe) form factor card having a length 101 of 254 mm and a single slot thickness 102 of 14.47 mm (the height dimension (of 111.15 mm) is not observable in FIG. 1). These dimensions fit within a maximum allowed envelope of 312 mm (length).

As observed in FIG. 1, the accelerator card 100 has a plurality of high performance system on chips (SOCs) 103_1, 103_2, 103_3 such one or more general purpose processor chips (CPUs) or graphics processor chips (GPUs). Each of the SOCs 103_1, 103_2, 103_3 have ball grid array (BGA) I/Os on the underside of their respective packages to attach to the printed circuit board (PCB) 104. An extended single mass of metal 105 is mounted to a backplate 106 and ideally touches all of the SOC package lids 103_1, 103_2, 103_3 so that a common heat sink 105 is formed.

A problem with the common heat sink 105 is that it creates high thermal resistance in the interface between the SOC package lids 103_1, 103_2, 103_3 and the heat sink 105. Here, there is some tolerance with respect to the mechanical positioning of the SOC packages 103_1, 103_2, 103_3 relative to one another.

Specifically, during the attachment of the SOC packages 103_1, 103_2, 103_3 to the printed circuit board 104, there can be different unevenness during the melting of the respective BGA solder balls underneath the different SOC packages 103_1, 103_2, 103_3. The different unevenness results in the SOC package lids 103_1, 103_2, 103_3 residing at different vertical heights above the printed circuit board 104 and/or exhibiting different two or three dimensional “tilts”.

The different positionings of the SOC package lids 103_1, 103_2, 103_3 result in gaps or other kinds of sub-optimal interfacing between the common heat sink 105 and the SOC packages 103_1, 103_2, 103_3. As observed in FIG. 1, the left most SOC package 103_1 is tilted to the right resulting in a gap between the upper right corner of the SOC package 103_1 and the heat sink 105, and, the right most SOC package 103_3 is tilted to the left resulting in a gap between the upper left corner of the SOC package 103_3 and the heat sink 105.

Here, particularly with the common heat sink 105 having some appreciable thickness so that it can absorb the combined heat from multiple high performance semiconductor chips, the common heat sink 105 is unable to morph its surface structure so that it is flush against the full surface of the SOCs package lids 103_1, 103_2, 103_3 with their varying heights/tilts.

Moreover, thermal cross talk can exist between the cooling dynamics of the different SOCs 103_1, 103_2, 103_3 and their surrounding components. Specifically, if one of the SOCs is heavily utilized and heats the common heat sink 105, it can have the adverse effect of increasing the temperature of a chip in one of the other SOC packages thereby adversely affecting the chip's performance.

The common heat sink 105 provides straightforward manufacturability of the overall card 100 and ensures that the vertical profile of the card stays within its 14.47 mm thickness 102 specification. However, these are achieved at the expense of thermal efficiency, which is contrary to future trends of increasing SOC heat dissipation and increasing number of SOCs per card.

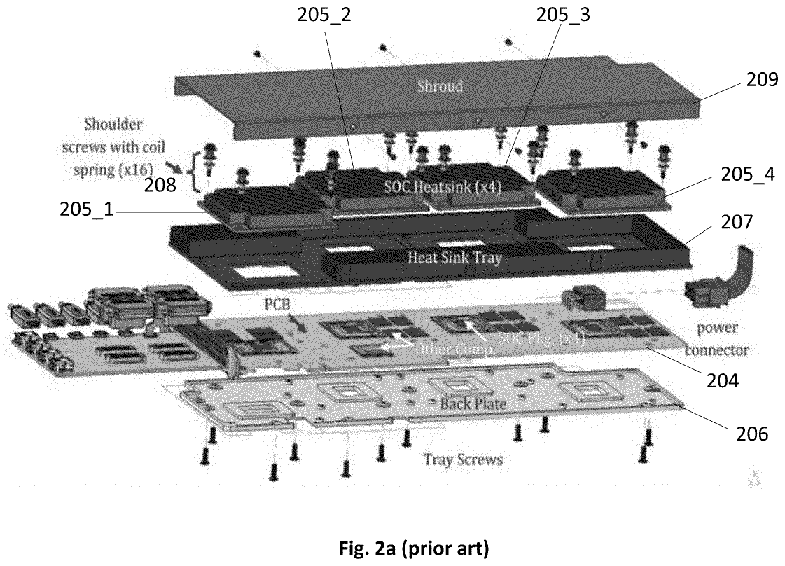

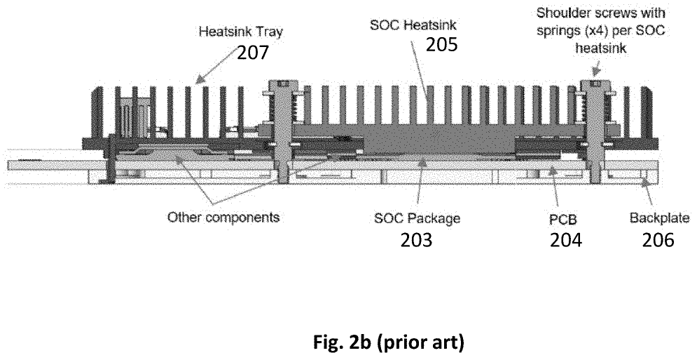

FIGS. 2a and 2b depict another prior art add-in card is that improves over the prior art add-in card of FIG. 1 by attaching individual heat sinks 205_1, 205_2, 205_3, 205_4 to the different SOCs.

FIG. 2a shows an exploded view in which a heat sink tray 207 is bolted to the back plate 206. The SOCs are mounted to respective I/Os on the printed circuit board 204 through corresponding window openings in the heat sink tray 207. Separate heat sinks 205_1, 205_2, 205_3, 205_4 are then individually mounted to the heat sink tray 207. Importantly, the fixturing mechanism 208 between the heat sinks 205 and the heat sink tray 207 is spring loaded which allows flush interfacing between the undersurfaces of the heat sinks 205 and their respective SOC package lids.

As observed in FIGS. 2a and 2b, each heat sink 205_1, 205_2, 205_3, 205_4 is mounted to the back plate 206 at its four corner with a spring loaded screw 208. The spring loading of the screws provides for different tightening experiences at the four corners of each heat sink as a function of the different vertical heights of the SOC package at these four corners.

Specifically, for example, if the SOC package has some tilt, one of the SOC package corners will sit higher off the printed circuit board 204 than another (e.g., opposite) SOC package corner. In this case, the screw at the higher corner will be tightened with fewer threaded rotations of the screw than the lower corner which orients the underside of the heat sink to be flush against the tilted package lid.

The spring loading also applies pressure from the heat sink underside to the SOC package lid. That is, the spring compresses as the screw is threaded into the back plate 206. As such, the “push back” of the spring causes the heat sink to pushed into the SOC package lid after the tightening is complete. Screws are just one type of fixturing element which can be used. Other fixturing elements that can be used in a spring loaded fashion include bolts, torsion bars, etc.

The custom fitting of the individual heat sinks 205_1, 205_2, 205_3, 205_4 to the different SOCs improves overall thermal cooling efficiency between the SOC packages and the cooling assembly as compared to the prior art card of FIG. 1. To the extent there are edges or other unevenness in the vertical profile of the card that results from the individual heat sinks, and the same could be a concern regarding ease of installation of the card in tight spaces/slots, as observed in FIG. 2a, a shroud 209 can be placed over the heat sinks to create a planar outer surface of the card.

Heat sinks 205_1, 205_2, 205_3, 205_4 are constructed as narrow fins that emanate from a base. Air flows through the openings between the fins. The individual cooling of the SOCs with their own respective heat sinks 205_1, 205_2, 205_3, 205_4 not only results in improved cooling efficiency for each SOC but also diminishes thermal cross talk between the SOCs (the heat generated by one SOC package does not appreciably heat the semiconductor die of another SOC package).

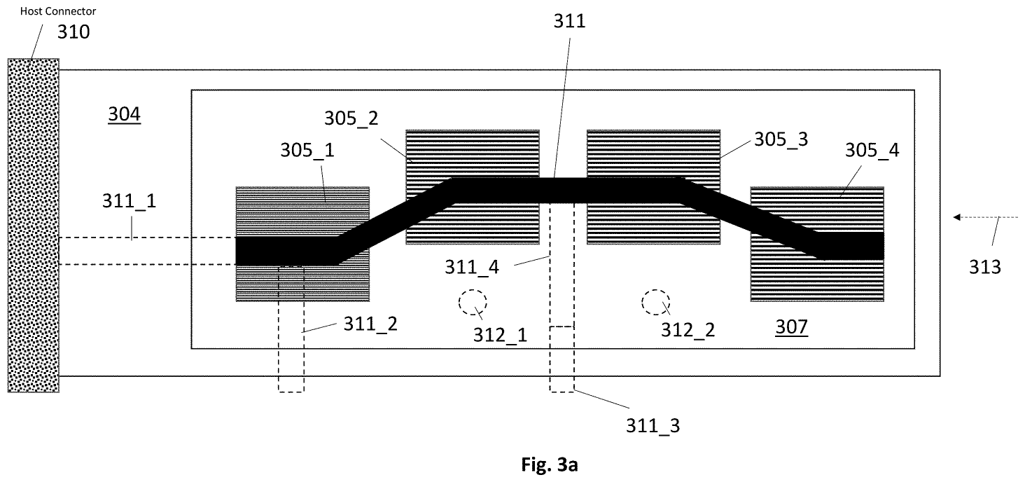

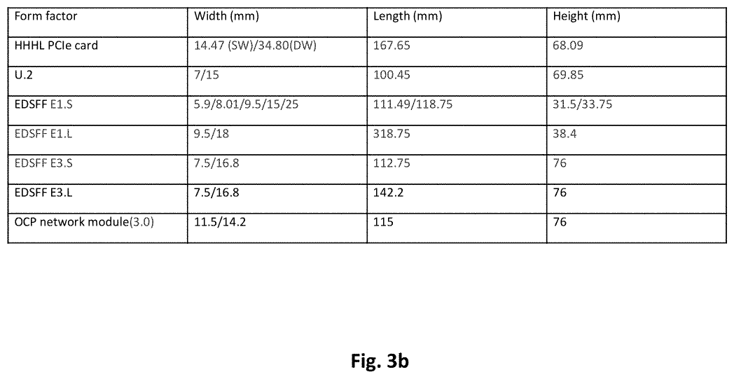

FIG. 3a shows additional improvements that can be made to the prior art add-in card of FIGS. 2a and 2b. FIG. 3a shows a top down view of the card. The heat sink tray 307 is observable over the printed circuit board 304. The heat sinks 305_1, 305_2, 305_3 and 305_4 are attached to their respective SOCs through the window openings in the heat sink tray 307.

A first improvement concerns the realization that the heat sinks 305_1, 305_2, 305_3 and 305_4 are cooled with ambient of different temperatures. Specifically, the heat sinks are principally cooled by a cool air flow 313 that enters from the back edge of the card. As a consequence, heat sink 305_4 receives principally cool air, whereas, the air that flows through the remaining heat sinks becomes progressively warmer because the air flow absorbs heat from the fins of the preceding heat sinks.

As such, the air that flows through the last heat sink 305_1 has already been warmed by its three preceding heat sinks 305_2, 305_3 and 305_4. This puts the SOC beneath heat sink 305_1 at a cooling disadvantage which can become a performance limitation of the card (the workload of the SOC or card will be limited by the SOC's temperature).

Thus, a first improvement is to enhance the cooling properties of heat sink 305_1 as compared to the other heat sinks 305_2, 305_3 and 305_4. As observed in FIG. 3, heat sink 305_1 therefore has more fins than heat sinks 305_2, 305_3 and 305_4. Integrating more fins (e.g., through finer fin pitch) on heat sink 305_1 causes heat sink 305_1 to have lower thermal resistance between itself and the ambient as compared to the other heat sinks 305_2, 305_3 and 305_4. As a consequence, the SOC beneath heat sink 305_1 will be cooled comparably with the other SOCs even through the SOC beneath heat sink 305_1 is cooled with warmer air than the other SOCs.

Another improvement is the presence of a heat pipe 311 that runs across the tops of the heat sinks 305_1, 305_2, 305_3, 305_4. Here, heat pipe 311 transports some of the cooler ambient associated with air flow 313 near heat sink 305_4 more evenly across the remaining heat sinks 305_3, 305_2, 305_1 such that the progression of increasingly warmer air from the back of the card toward the card's host interface 310 is mitigated. Said another way, the difference in ambient temperature between heat sink 305_4 and 305_1 is reduced with the presence of heat pipe 311 as compared to an embodiment when the heat pipe 311 is not present.

In various embodiments the heat pipe 311 is a nearly flat pipe having fairly wide width (observable in FIG. 3a), e.g., on the order 10 mm or more, but small thickness or height (perpendicular to the plane of FIG. 3a), e.g., on the order of a few mm. In various embodiments the heat pipe helps in the transfer of heat from the heat sink 305_1 near the host interface to the heat sink 305_4 near the cool air inlet 313. In various embodiments the heat pipe 311 is composed of copper or other similar thermally conductive material and is brazed to the top surfaces of the heat sinks 305_1, 305_2, 305_3, 305_4.

Notably, being of modest thickness/height in the dimension that is perpendicular to the plane of FIG. 3, the heat pipe 311 has some flexibility and can be bent so that it conforms its shape to the different tilt of the different heat sinks. As such, its flat, wide undersurface can be pressed/brazed flush against the top surfaces of the heat sinks 305_1, 305_2, 305_3, 305_4.

FIG. 3a also shows different approaches for attaching or running the heat pipe 311 to one or more cold plates or cooler surfaces. Here, by attached the heat pipe 311 to a cooler surface, the ability of the heat pipe to maintain a cool ambient within its hollow opening is enhanced which further reduces the difference in ambient temperature between heat sink 305_4 and heat sink 305_1. Moreover, thermal cross talk between the heat sinks created by the heat pipe is reduced/minimized with the attachment of the heat pipe 311 to the one or more cold plates or cooler surfaces.

According to a first approach a section of the heat pipe 311_1 runs to the host interface 310 or otherwise to a chassis component that serves as a cold mass that the heat pipe is thermally coupled to. For example, the heat pipe 311_1 is placed in contact with a cool metal mass that is near the host interface 310 and is mechanically integrated with the chassis of the system that the add-in card is plugged into.

According to a second approach, a section of the heat pipe 311_2 wraps around the edge of the card (or runs through the heat sink tray 307 and printed circuit board 304) and is thermally coupled to the back plate (which is not observable in FIG. 3a because it is beneath the printed circuit board). Here, the back plate can be cooled with air flow 313 and/or be coupled with a cold plate that is integrated with the chassis that the add-in card is plugged into.

Both of the above approaches 311_1, 311_2 thermally couple the heat pipe 311 near the heat sink 305_1 that receives the warmest air and therefore further mitigates ambient temperature difference between heat sink 305_1 and 305_4 (by “anchoring” the air in the heat pipe 311 to a cold mass near heat sink 305_1).

According to a third approach, a section of the heat pipe 311_3 wraps around the edge of the card (or runs through the heat sink tray 307 and printed circuit board 304) and is thermally coupled to the back plate as described above but the heat pipe emanates from the main pipe 311 near the middle of the card.

According to a fourth approach a section of the heat pipe 311_4 is thermally coupled to a cooler portion of the heat sink tray 307. Here, the heat sink tray 307 is thermally conductive, but areas of the heat sink tray 307 that are close to the SOCs will be warmer than areas of the heat sink tray 307 that are farther away from the heat sink tray 307. In the case of the layout of the card of FIG. 3, the areas in and around regions 312_1 and 312_2 will be cooler because these areas are not near any SOCs.

As such, for example, the heat pipe section 311_4 is thermally coupled to the heat sink tray 307 in an area between regions 312_1, 312_2.

The above approaches concerning the different heat pipe sections 311_1, 311_2, 311_3, 311_4 can be combined in various ways. At a first extreme, only one of these approaches is utilized for a single card. At another extreme, all of these approaches are utilized for a single card. In other in-between approaches, two or three of these approaches are utilized for a single card.

In any of these approaches, or in another alternative approach, the thermal resistance between the heat sink tray 307 and the back plate is reduced by mechanically connecting them with material having a lower thermal resistance than stainless steel. Here, the heat sink tray 207 is mechanically coupled to the back plate 206 in the prior art card of FIGS. 2a,b. However, the heat sink tray 207 is at best weakly thermally coupled to the back plate 206 because the mechanical connection between them is made with stainless steel screws.

By contrast, in the improved card of FIG. 3a, there exist deliberate mechanical connections composed of material having higher thermal conductivity than stainless steel so that they heat sink tray 307 is thermally coupled to the back plate (as well as mechanically coupled).

In one approach, screws having an inner core of copper (or other material having higher thermal conductivity than stainless steel) and outer surface of stainless steel are used to mechanically connect the heat sink tray 307 to the back plate. Here, the stainless steel is used for strength whereas the cooper is used for thermal coupling. Such screws can be used in place of the stainless steel mechanical screws, or the stainless steel mechanical screws can remain and more screws having a copper core are added to the tray/plate mechanical connection for thermal conductivity.

According to a first approach, a screw composed of copper is inserted into a tube of stainless steel. The stainless steel tube is then press fit and brazed into the threads of the copper screw. According to a second approach, the core of a stainless steel screw is bored out and the remaining cavity is filled with copper and brazed.

In a combined or alternate approach, besides screws, posts or studs composed of copper, e.g., in regions 312_1, 312_2, run through openings in the printed circuit board 304 and are mechanically connected on their ends to the heat sink tray 307 and back plate. Such studs/posts create low thermal resistance between the heat sink tray 307 and back plate thereby anchoring a low temperature to the heat sink tray via the cold plate (which as described above can be coupled to a cooling mass in the system chassis). In alternate or combined approaches bolts or other fixturing elements having copper as described above are utilized.

In still further embodiments the heat sinks 305_1, 305_2, 305_3 and 305_4 are replaced with corresponding structures for liquid cooling such as a cold plates or vapor chambers. Any/all of the above described cooling improvements can still be applied.

SOC is a general term for a high performance, high density semiconductor chip. Some SOCs are accelerators (e.g., GPUs, inference engines, machine learning ASICs) whereas other SOCs can have other uses (e.g., network processing if the add in card is a network adaptor card). In various embodiments, the respective packages for the high performance semiconductor chips each have 5,000 I/Os or more and can be BGA or land-grid array (LGA) that plugs into a socket that is mounted on the circuit board.

Although embodiments above have been directed to a PCIe form factor add-in card, the teachings above can be applied to other add-in card (including small form factor add-in cards) such as any of those listed in FIG. 3b.

Although the discussion of the embodiment of FIG. 3a stresses the heat pipe being in contact with each of the dedicated heat sinks 305_1, 305_2, 305_3 and 305_4, in other embodiments the heat pipe is in contact with less than all of the heat sinks (e.g., the heat pipe is not connected to the heat sink 305_4 that directly receives the cool air 313).

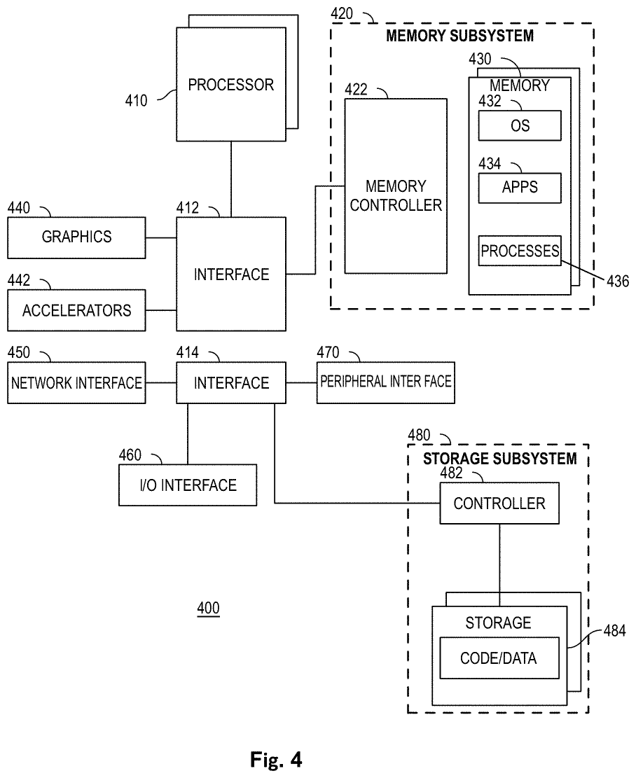

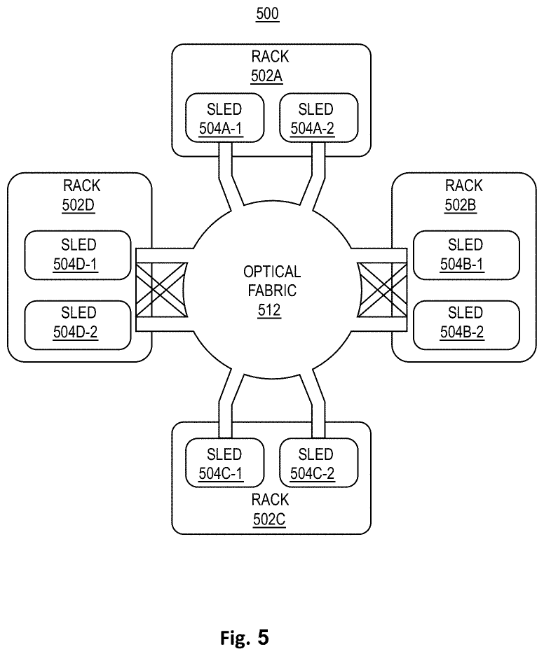

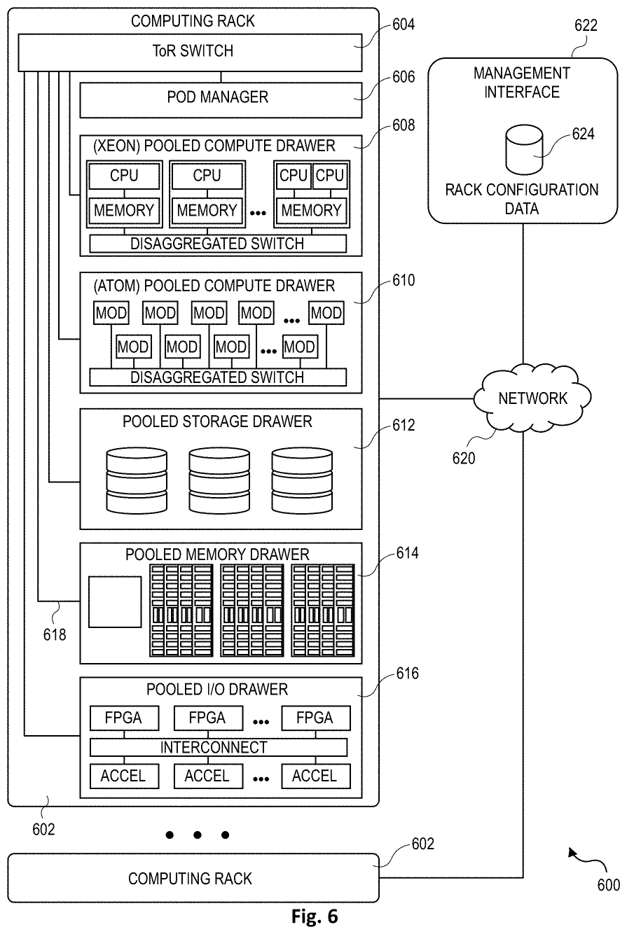

The following discussion concerning FIGS. 4, 5 and 6 are directed to systems, data centers and rack implementations, generally. FIG. 4 generally describes possible features of an electronic system that can include an add-in (e.g., accelerator) card having multiple high performance semiconductor chip packages, each having its own heat sink as described above. FIG. 5 describes possible features of a data center that can include such electronic systems. FIG. 6 describes possible features of a rack having one or more such electronic systems installed into it.

FIG. 4 depicts an example system. System 400 includes processor 410, which provides processing, operation management, and execution of instructions for system 400. Processor 410 can include any type of microprocessor, central processing unit (CPU), graphics processing unit (GPU), processing core, or other processing hardware to provide processing for system 400, or a combination of processors. Processor 410 controls the overall operation of system 400, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

Certain systems also perform networking functions (e.g., packet header processing functions such as, to name a few, next nodal hop lookup, priority/flow lookup with corresponding queue entry, etc.), as a side function, or, as a point of emphasis (e.g., a networking switch or router). Such systems can include one or more network processors (NPUs) to perform such networking functions (e.g., in a pipelined fashion or otherwise).

In one example, system 400 includes interface 412 coupled to processor 410, which can represent a higher speed interface or a high throughput interface for system components that needs higher bandwidth connections, such as memory subsystem 420 or graphics interface components 440, or accelerators 442. Interface 412 represents an interface circuit, which can be a standalone component or integrated onto a processor die. Where present, graphics interface 440 interfaces to graphics components for providing a visual display to a user of system 400. In one example, graphics interface 440 can drive a high definition (HD) display that provides an output to a user. High definition can refer to a display having a pixel density of approximately 100 PPI (pixels per inch) or greater and can include formats such as full HD (e.g., 1080p), retina displays, 4K (ultra-high definition or UHD), or others. In one example, the display can include a touchscreen display. In one example, graphics interface 440 generates a display based on data stored in memory 430 or based on operations executed by processor 410 or both. In one example, graphics interface 440 generates a display based on data stored in memory 430 or based on operations executed by processor 410 or both.

Accelerators 442 can be implemented, e.g., as a plug-in or add-in card having multiple high performance accelerator chip packages each with its own heat sink as described at length above. Accelerators 442 can be a fixed function offload engine that can be accessed or used by a processor 410. For example, an accelerator among accelerators 442 can provide compression (DC) capability, cryptography services such as public key encryption (PKE), cipher, hash/authentication capabilities, decryption, or other capabilities or services. In some embodiments, in addition or alternatively, an accelerator among accelerators 442 provides field select controller capabilities as described herein. In some cases, accelerators 442 can be integrated into a CPU socket (e.g., a connector to a motherboard or circuit board that includes a CPU and provides an electrical interface with the CPU). For example, accelerators 442 can include a single or multi-core processor, graphics processing unit, logical execution unit single or multi-level cache, functional units usable to independently execute programs or threads, application specific integrated circuits (ASICs), neural network processors (NNPs), “X” processing units (XPUs), programmable control logic circuitry, and programmable processing elements such as field programmable gate arrays (FPGAs). Accelerators 442 can provide multiple neural networks, processor cores, or graphics processing units can be made available for use by artificial intelligence (AI) or machine learning (ML) models. For example, the AI model can use or include any or a combination of: a reinforcement learning scheme, Q-learning scheme, deep-Q learning, or Asynchronous Advantage Actor-Critic (A3C), combinatorial neural network, recurrent combinatorial neural network, or other AI or ML model. Multiple neural networks, processor cores, or graphics processing units can be made available for use by AI or ML models.

Memory subsystem 420 represents the main memory of system 400 and provides storage for code to be executed by processor 410, or data values to be used in executing a routine. Memory subsystem 420 can include one or more memory devices 430 such as read-only memory (ROM), flash memory, volatile memory, or a combination of such devices. Memory 430 stores and hosts, among other things, operating system (OS) 432 to provide a software platform for execution of instructions in system 400. Additionally, applications 434 can execute on the software platform of OS 432 from memory 430. Applications 434 represent programs that have their own operational logic to perform execution of one or more functions. Processes 436 represent agents or routines that provide auxiliary functions to OS 432 or one or more applications 434 or a combination. OS 432, applications 434, and processes 436 provide software functionality to provide functions for system 400. In one example, memory subsystem 420 includes memory controller 422, which is a memory controller to generate and issue commands to memory 430. It will be understood that memory controller 422 could be a physical part of processor 410 or a physical part of interface 412. For example, memory controller 422 can be an integrated memory controller, integrated onto a circuit with processor 410. In some examples, a system on chip (SOC or SoC) combines into one SoC package one or more of: processors, graphics, memory, memory controller, and Input/Output (I/O) control logic circuitry.

A volatile memory is memory whose state (and therefore the data stored in it) is indeterminate if power is interrupted to the device. Dynamic volatile memory requires refreshing the data stored in the device to maintain state. One example of dynamic volatile memory incudes DRAM (Dynamic Random Access Memory), or some variant such as Synchronous DRAM (SDRAM). A memory subsystem as described herein may be compatible with a number of memory technologies, such as DDR3 (Double Data Rate version 3, original release by JEDEC (Joint Electronic Device Engineering Council) on Jun. 27, 2007). DDR4 (DDR version 4, initial specification published in September 2012 by JEDEC), DDR4E (DDR version 4), LPDDR3 (Low Power DDR version3, JESD209-3B, August 2013 by JEDEC), LPDDR4) LPDDR version 4, JESD209-4, originally published by JEDEC in August 2014), WIO2 (Wide Input/Output version 2, JESD229-2 originally published by JEDEC in August 2014, HBM (High Bandwidth Memory), JESD235, originally published by JEDEC in October 2013, LPDDR5, HBM2 (HBM version 2), or others or combinations of memory technologies, and technologies based on derivatives or extensions of such specifications.

In various implementations, memory resources can be “pooled”. For example, the memory resources of memory modules installed on multiple cards, blades, systems, etc. (e.g., that are inserted into one or more racks) are made available as additional main memory capacity to CPUs and/or servers that need and/or request it. In such implementations, the primary purpose of the cards/blades/systems is to provide such additional main memory capacity. The cards/blades/systems are reachable to the CPUs/servers that use the memory resources through some kind of network infrastructure such as CXL, CAPI, etc.

The memory resources can also be tiered (different access times are attributed to different regions of memory), disaggregated (memory is a separate (e.g., rack pluggable) unit that is accessible to separate (e.g., rack pluggable) CPU units), and/or remote (e.g., memory is accessible over a network).

While not specifically illustrated, it will be understood that system 400 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect express (PCIe) bus, a HyperTransport or industry standard architecture (ISA) bus, a small computer system interface (SCSI) bus, Remote Direct Memory Access (RDMA), Internet Small Computer Systems Interface (iSCSI), NVM express (NVMe), Coherent Accelerator Interface (CXL), Coherent Accelerator Processor Interface (CAPI), Cache Coherent Interconnect for Accelerators (CCIX), Open Coherent Accelerator Processor (Open CAPI) or other specification developed by the Gen-z consortium, a universal serial bus (USB), or an Institute of Electrical and Electronics Engineers (IEEE) standard 1394 bus.

In one example, system 400 includes interface 414, which can be coupled to interface 412. In one example, interface 414 represents an interface circuit, which can include standalone components and integrated circuitry. In one example, multiple user interface components or peripheral components, or both, couple to interface 414. Network interface 450 provides system 400 the ability to communicate with remote devices (e.g., servers or other computing devices) over one or more networks. Network interface 450 can include an Ethernet adapter, wireless interconnection components, cellular network interconnection components, USB (universal serial bus), or other wired or wireless standards-based or proprietary interfaces. Network interface 450 can transmit data to a remote device, which can include sending data stored in memory. Network interface 450 can receive data from a remote device, which can include storing received data into memory. Various embodiments can be used in connection with network interface 450, processor 410, and memory subsystem 420.

In one example, system 400 includes one or more input/output (I/O) interface(s) 460. I/O interface 460 can include one or more interface components through which a user interacts with system 400 (e.g., audio, alphanumeric, tactile/touch, or other interfacing). Peripheral interface 470 can include any hardware interface not specifically mentioned above. Peripherals refer generally to devices that connect dependently to system 400. A dependent connection is one where system 400 provides the software platform or hardware platform or both on which operation executes, and with which a user interacts.

In one example, system 400 includes storage subsystem 480 to store data in a nonvolatile manner. In one example, in certain system implementations, at least certain components of storage 480 can overlap with components of memory subsystem 420. Storage subsystem 480 includes storage device(s) 484, which can be or include any conventional medium for storing large amounts of data in a nonvolatile manner, such as one or more magnetic, solid state, or optical based disks, or a combination. Storage 484 holds code or instructions and data in a persistent state (e.g., the value is retained despite interruption of power to system 400). Storage 484 can be generically considered to be a “memory,” although memory 430 is typically the executing or operating memory to provide instructions to processor 410. Whereas storage 484 is nonvolatile, memory 430 can include volatile memory (e.g., the value or state of the data is indeterminate if power is interrupted to system 400). In one example, storage subsystem 480 includes controller 482 to interface with storage 484. In one example controller 482 is a physical part of interface 414 or processor 410 or can include circuits in both processor 410 and interface 414.

A non-volatile memory (NVM) device is a memory whose state is determinate even if power is interrupted to the device. In one embodiment, the NVM device can comprise a block addressable memory device, such as NAND technologies, or more specifically, multi-threshold level NAND flash memory (for example, Single-Level Cell (“SLC”), Multi-Level Cell (“MLC”), Quad-Level Cell (“QLC”), Tri-Level Cell (“TLC”), or some other NAND). A NVM device can also comprise a byte-addressable write-in-place three dimensional cross point memory device, or other byte addressable write-in-place NVM device (also referred to as persistent memory), such as single or multi-level Phase Change Memory (PCM) or phase change memory with a switch (PCMS), NVM devices that use chalcogenide phase change material (for example, chalcogenide glass), resistive memory including metal oxide base, oxygen vacancy base and Conductive Bridge Random Access Memory (CB-RAM), nanowire memory, ferroelectric random access memory (FeRAM, FRAM), magneto resistive random access memory (MRAM) that incorporates memristor technology, spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory.

A power source (not depicted) provides power to the components of system 400. More specifically, power source typically interfaces to one or multiple power supplies in system 400 to provide power to the components of system 400. In one example, the power supply includes an AC to DC (alternating current to direct current) adapter to plug into a wall outlet. Such AC power can be renewable energy (e.g., solar power) power source. In one example, power source includes a DC power source, such as an external AC to DC converter. In one example, power source or power supply includes wireless charging hardware to charge via proximity to a charging field. In one example, power source can include an internal battery, alternating current supply, motion-based power supply, solar power supply, or fuel cell source.

In an example, system 400 can be implemented as a disaggregated computing system. For example, the system 400 can be implemented with interconnected compute sleds of processors, memories, storages, network interfaces, and other components. High speed interconnects can be used such as PCIe, Ethernet, or optical interconnects (or a combination thereof). For example, the sleds can be designed according to any specifications promulgated by the Open Compute Project (OCP) or other disaggregated computing effort, which strives to modularize main architectural computer components into rack-pluggable components (e.g., a rack pluggable processing component, a rack pluggable memory component, a rack pluggable storage component, a rack pluggable accelerator component, etc.).

Although a computer is largely described by the above discussion of FIG. 4, other types of systems to which the above described invention can be applied and are also partially or wholly described by FIG. 4 are communication systems such as routers, switches and base stations.

FIG. 5 depicts an example of a data center. Various embodiments can be used in or with the data center of FIG. 5. As shown in FIG. 5, data center 500 may include an optical fabric 512. Optical fabric 512 may generally include a combination of optical signaling media (such as optical cabling) and optical switching infrastructure via which any particular sled in data center 500 can send signals to (and receive signals from) the other sleds in data center 500. However, optical, wireless, and/or electrical signals can be transmitted using fabric 512. The signaling connectivity that optical fabric 512 provides to any given sled may include connectivity both to other sleds in a same rack and sleds in other racks.

Data center 500 includes four racks 502A to 502D and racks 502A to 502D house respective pairs of sleds 504A-1 and 504A-2, 504B-1 and 504B-2, 504C-1 and 504C-2, and 504D-1 and 504D-2. Thus, in this example, data center 500 includes a total of eight sleds. Optical fabric 512 can provide sled signaling connectivity with one or more of the seven other sleds. For example, via optical fabric 512, sled 504A-1 in rack 502A may possess signaling connectivity with sled 504A-2 in rack 502A, as well as the six other sleds 504B-1, 504B-2, 504C-1, 504C-2, 504D-1, and 504D-2 that are distributed among the other racks 502B, 502C, and 502D of data center 500. The embodiments are not limited to this example. For example, fabric 512 can provide optical and/or electrical signaling.

FIG. 6 depicts an environment 600 that includes multiple computing racks 602, each including a Top of Rack (ToR) switch 604, a pod manager 606, and a plurality of pooled system drawers. Generally, the pooled system drawers may include pooled compute drawers and pooled storage drawers to, e.g., effect a disaggregated computing system. Optionally, the pooled system drawers may also include pooled memory drawers and pooled Input/Output (I/O) drawers. In the illustrated embodiment the pooled system drawers include an INTEL® XEON® pooled computer drawer 608, and INTEL® ATOM™ pooled compute drawer 610, a pooled storage drawer 612, a pooled memory drawer 614, and a pooled I/O drawer 616. Each of the pooled system drawers is connected to ToR switch 604 via a high-speed link 618, such as a 40 Gigabit/second (Gb/s) or 100 Gb/s Ethernet link or an 100+Gb/s Silicon Photonics (SiPh) optical link. In one embodiment high-speed link 618 comprises an 600 Gb/s SiPh optical link.

Again, the drawers can be designed according to any specifications promulgated by the Open Compute Project (OCP) or other disaggregated computing effort, which strives to modularize main architectural computer components into rack-pluggable components (e.g., a rack pluggable processing component, a rack pluggable memory component, a rack pluggable storage component, a rack pluggable accelerator component, etc.).

Multiple of the computing racks 600 may be interconnected via their ToR switches 604 (e.g., to a pod-level switch or data center switch), as illustrated by connections to a network 620. In some embodiments, groups of computing racks 602 are managed as separate pods via pod manager(s) 606. In one embodiment, a single pod manager is used to manage all of the racks in the pod. Alternatively, distributed pod managers may be used for pod management operations. Rack environment 600 further includes a management interface 622 that is used to manage various aspects of the RSD environment. This includes managing rack configuration, with corresponding parameters stored as rack configuration data 624.

Any of the systems, data centers or racks discussed above, apart from being integrated in a typical data center, can also be implemented in other environments such as within a bay station, or other micro-data center, e.g., at the edge of a network.

In various embodiments multiple computer systems that are plugged into racks implement functionality of a data center through execution of software that invokes acceleration, where, the acceleration is performed at least in part with an accelerator add-in card that is plugged into one of the multiple computer systems. The add-in card has the improvements described at length above.

Embodiments herein may be implemented in various types of computing, smart phones, tablets, personal computers, and networking equipment, such as switches, routers, racks, and blade servers such as those employed in a data center and/or server farm environment. The servers used in data centers and server farms comprise arrayed server configurations such as rack-based servers or blade servers. These servers are interconnected in communication via various network provisions, such as partitioning sets of servers into Local Area Networks (LANs) with appropriate switching and routing facilities between the LANs to form a private Intranet. For example, cloud hosting facilities may typically employ large data centers with a multitude of servers. A blade comprises a separate computing platform that is configured to perform server-type functions, that is, a “server on a card.” Accordingly, each blade includes components common to conventional servers, including a main printed circuit board (main board) providing internal wiring (e.g., buses) for coupling appropriate integrated circuits (ICs) and other components mounted to the board.

Various examples may be implemented using hardware elements, software elements, or a combination of both. In some examples, hardware elements may include devices, components, processors, microprocessors, circuits, circuit elements (e.g., transistors, resistors, capacitors, inductors, and so forth), integrated circuits, ASICs, PLDs, DSPs, FPGAs, memory units, logic gates, registers, semiconductor device, chips, microchips, chip sets, and so forth. In some examples, software elements may include software components, programs, applications, computer programs, application programs, system programs, machine programs, operating system software, middleware, firmware, software modules, routines, subroutines, functions, methods, procedures, software interfaces, APIs, instruction sets, computing code, computer code, code segments, computer code segments, words, values, symbols, or any combination thereof. Determining whether an example is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given implementation.

Some examples may be implemented using or as an article of manufacture or at least one computer-readable medium. A computer-readable medium may include a non-transitory storage medium to store program code. In some examples, the non-transitory storage medium may include one or more types of computer-readable storage media capable of storing electronic data, including volatile memory or non-volatile memory, removable or non-removable memory, erasable or non-erasable memory, writeable or re-writeable memory, and so forth. In some examples, the program code implements various software elements, such as software components, programs, applications, computer programs, application programs, system programs, machine programs, operating system software, middleware, firmware, software modules, routines, subroutines, functions, methods, procedures, software interfaces, API, instruction sets, computing code, computer code, code segments, computer code segments, words, values, symbols, or any combination thereof.

According to some examples, a computer-readable medium may include a non-transitory storage medium to store or maintain instructions that when executed by a machine, computing device or system, cause the machine, computing device or system to perform methods and/or operations in accordance with the described examples. The instructions may include any suitable type of code, such as source code, compiled code, interpreted code, executable code, static code, dynamic code, and the like. The instructions may be implemented according to a predefined computer language, manner or syntax, for instructing a machine, computing device or system to perform a certain function. The instructions may be implemented using any suitable high-level, low-level, object-oriented, visual, compiled and/or interpreted programming language.

To the extent any of the teachings above can be embodied in a semiconductor chip, a description of a circuit design of the semiconductor chip for eventual targeting toward a semiconductor manufacturing process can take the form of various formats such as a (e.g., VHDL or Verilog) register transfer level (RTL) circuit description, a gate level circuit description, a transistor level circuit description or mask description or various combinations thereof. Such circuit descriptions, sometimes referred to as “IP Cores”, are commonly embodied on one or more computer readable storage media (such as one or more CD-ROMs or other type of storage technology) and provided to and/or otherwise processed by and/or for a circuit design synthesis tool and/or mask generation tool. Such circuit descriptions may also be embedded with program code to be processed by a computer that implements the circuit design synthesis tool and/or mask generation tool.

The appearances of the phrase “one example” or “an example” are not necessarily all referring to the same example or embodiment. Any aspect described herein can be combined with any other aspect or similar aspect described herein, regardless of whether the aspects are described with respect to the same figure or element. Division, omission or inclusion of block functions depicted in the accompanying figures does not infer that the hardware components, circuits, software and/or elements for implementing these functions would necessarily be divided, omitted, or included in embodiments.

Some examples may be described using the expression “coupled” and “connected” along with their derivatives. These terms are not necessarily intended as synonyms for each other. For example, descriptions using the terms “connected” and/or “coupled” may indicate that two or more elements are in direct physical or electrical contact with each other. The term “coupled,” however, may also mean that two or more elements are not in direct contact with each other, but yet still co-operate or interact with each other.

The terms “first,” “second,” and the like, herein do not denote any order, quantity, or importance, but rather are used to distinguish one element from another. The terms “a” and “an” herein do not denote a limitation of quantity, but rather denote the presence of at least one of the referenced items. The term “asserted” used herein with reference to a signal denote a state of the signal, in which the signal is active, and which can be achieved by applying any logic level either logic 0 or logic 1 to the signal. The terms “follow” or “after” can refer to immediately following or following after some other event or events. Other sequences may also be performed according to alternative embodiments. Furthermore, additional sequences may be added or removed depending on the particular applications. Any combination of changes can be used and one of ordinary skill in the art with the benefit of this disclosure would understand the many variations, modifications, and alternative embodiments thereof.

Disjunctive language such as the phrase “at least one of X, Y, or Z,” unless specifically stated otherwise, is otherwise understood within the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present. Additionally, conjunctive language such as the phrase “at least one of X, Y, and Z,” unless specifically stated otherwise, should also be understood to mean X, Y, Z, or any combination thereof, including “X, Y, and/or Z.”

1. An apparatus, comprising:
an add-in card comprising multiple semiconductor chip packages mounted to a printed circuit board of the add-in card, separate dedicated heat sinks respectively coupled to the semiconductor chip packages with spring loaded fixturing elements, a heat pipe coupled to a plurality of the heat sinks.

2. The apparatus of claim 1 wherein the add-in card is a PCIe card.

3. The apparatus of claim 1 wherein the add-in card is an accelerator add-in card.

4. The apparatus of claim 1 wherein one of the separate dedicated heat sinks is to receive air that has been warmed by flowing through another one of the separate dedicated heat sinks, the one separate dedicated heat sink having more fins than the other one of the separate dedicated heat sinks.

5. The apparatus of claim 1 wherein the heat pipe is to be thermally coupled to a chassis component of a system that the add-in card is to plug into.

6. The apparatus of claim 1 wherein the heat pipe is thermally coupled to a back plate of the add-in card.

7. The apparatus of claim 1 wherein the heat pipe is thermally coupled to a heat sink tray that resides between the separate dedicated heat sinks and the semiconductor chip packages.

8. The apparatus of claim 7 wherein the heat sink tray is thermally coupled to a back plate of the card with at least one of:
a screw comprised of copper;
a bolt comprised of copper;
a post comprised of copper.

9. A computer system, comprising:
a motherboard comprising one or more central processing units (CPUs);
an add-in card plugged into the computer system, the add-in card comprising multiple semiconductor chip packages mounted to a printed circuit board of the add-in card, separate dedicated heat sinks respectively coupled to the semiconductor chip packages with spring loaded fixturing elements, a heat pipe coupled to a plurality of the heat sinks.

10. The computer system of claim 9 wherein one of the separate dedicated heat sinks is to receive air that has been warmed by flowing through another one of the separate dedicated heat sinks, the one separate dedicated heat sink having more fins than the other one of the separate dedicated heat sinks.

11. The computer system of claim 9 wherein the heat pipe is to be thermally coupled to a chassis of the computer system.

12. The computer system of claim 9 wherein the heat pipe is thermally coupled to a back plate of the add-in card.

13. The computer system of claim 9 wherein the heat pipe is thermally coupled to a heat sink tray that resides between the separate dedicated heat sinks and the semiconductor chip packages.

14. The computer system of claim 13 wherein the heat sink tray is thermally coupled to a back plate of the add-in card with at least one of:
a screw comprised of copper;
a bolt comprised of copper;
a post comprised of copper.

15. A data center, comprising multiple computer systems plugged into multiple racks, the multiple computer systems communicatively coupled to one another by way of one or more networks, the multiple computer systems to implement functionality of the data center through execution of software that invokes acceleration, the acceleration performed at least in part with an accelerator add-in card that is plugged into one of the multiple computer systems, multiple semiconductor chip packages mounted to a printed circuit board of the add-in card, separate dedicated heat sinks respectively coupled to the semiconductor chip packages with spring loaded fixturing elements, a heat pipe coupled to a plurality of the heat sinks.

16. The data center system of claim 9 wherein one of the separate dedicated heat sinks is to receive air that has been warmed by flowing through another one of the separate dedicated heat sinks, the one separate dedicated heat sink having more fins than the other one of the separate dedicated heat sinks.

17. The data center system of claim 9 wherein the heat pipe is to be thermally coupled to a chassis of the computer system.

18. The data center of claim 9 wherein the heat pipe is thermally coupled to a back plate of the add-in card.

19. The data center of claim 9 wherein the heat pipe is thermally coupled to a heat sink tray that resides between the separate dedicated heat sinks and the semiconductor chip packages.

20. The data center of claim 13 wherein the heat sink tray is thermally coupled to a back plate of the add-in card with at least one of:
a screw comprised of copper;
a bolt comprised of copper;
a post comprised of copper.
